(19) United States
(12) Patent Application Publication
(10) Pub. No.: US 2004/0012043 A1
(43) Pub. Date: Jan. 22, 2004

(54) Novel dielectric stack and method of making same

(76) Inventors: F. Daniel Gealy, Kuna, ID (US); Vishnu K. Agarwal, Boise, ID (US)

Correspondence Address: WILLIAMS, MORGAN & AMERSON, P.C., 10333 RICHMOND, SUITE 1100, HOUSTON, TX, 77042, US

(21) Appl. No.: 10/197,042

(22) Filed: Jul. 17, 2002

(51) Int. Cl. H01L 27/108

(52) U.S. Cl. 257/303

(57) ABSTRACT

Disclosed herein are various novel dielectric stack combinations that may be used in integrated circuit devices, and various methods of making same. In one illustrative embodiment, a capacitor is provided which is comprised of a first conductive layer, a first dielectric layer formed above the first conductive layer, the first dielectric layer comprised of a material selected from the group consisting of hafnium silicate, zirconium silicate and aluminum silicate, a second dielectric layer formed above the first dielectric layer, the second dielectric layer comprised of a material selected from the group consisting of hafnium oxide, zirconium oxide and aluminum oxide, and a second conductive layer formed above the second dielectric layer. In another illustrative embodiment, a transistor is provided which is comprised of a gate electrode formed above a semiconducting substrate and a first and a second dielectric layer positioned between the substrate and the gate electrode, the second dielectric layer being positioned between the first dielectric layer and the gate electrode, the first dielectric layer being formed above the substrate and being comprised of a material selected from the group consisting of hafnium silicate, zirconium silicate and aluminum silicate, the second dielectric layer being comprised of a material selected from the group consisting of hafnium oxide, zirconium oxide and aluminum oxide.

### BACKGROUND OF THE INVENTION

1. Field of the Invention

This present invention is generally directed to the field of semiconductor processing, and, more particularly, to a novel dielectric stack that may be used in integrated circuit devices, and a method of making same.

2. Description of the Related Art

A dynamic random access memory (DRAM) cell typically comprises a charge storage capacitor (or cell capacitor) coupled to an access device such as a Metal-Oxide-Semiconductor Field Effect Transistor (MOSFET). The MOSFET functions to apply or remove charge on the capacitor, thus affecting a logical state defined by the stored charge. The amount of charge stored on the capacitor is determined by the capacitance C=∈∈_{O} A/d, where ∈ is the dielectric constant or permittivity of the capacitor dielectric, ∈_{O} is the vacuum permittivity, A is the electrode (or storage node) area, and d is the interelectrode spacing. The conditions of DRAM operation such as operating voltage, leakage rate and refresh rate, will in general mandate that a certain minimum charge be stored by the capacitor.

In the continuing trend to higher memory capacity, the packing density of storage cells must increase, while still maintaining and/or increasing the required capacitance levels. This is a crucial demand of DRAM fabrication technologies if future generations of expanded memory array devices are to be successfully manufactured. Nevertheless, in the trend to higher memory capacity, the packing density of cell capacitors has increased at the expense of available cell area. As cell areas have decreased, it has become more difficult to provide sufficient capacitance using conventional stacked capacitor structures. Yet, design and operational parameters determine the minimum charge required for reliable operation of the memory cell despite the decreasing cell area. Several techniques have been developed to increase the total charge capacity of the cell capacitor without significantly affecting the cell area. These include new structures utilizing trench and stacked capacitors, electrodes having textured surface morphology and new capacitor dielectric materials having higher dielectric constants.

As DRAM density has increased, thin film capacitors, such as stacked capacitors, trenched capacitors, or combinations thereof, have evolved in attempts to meet minimum space requirements. Many of these designs have become elaborate and difficult to fabricate consistently as well as efficiently. Furthermore, the recent generations of DRAMs are pushing thin film capacitors technology to the limit of processing capability. Thus, greater attention has been given to the development of thin film dielectric materials that possess a permittivity significantly greater than the conventional dielectrics used today, such as silicon oxides or nitrides.

The use of so-called “high-k” dielectric materials as gate dielectric layers and in DRAM capacitors has received much attention in recent years. However, in the case of metal-insulator-silicon (MIS) type structures, there is generally an interfacial dielectric layer of material positioned between the high-k dielectric material, e.g., an interfacial layer of silicon dioxide. The presence of this interfacial dielectric layer tends to erode the overall capacitance per unit area of the capacitor due to the relatively low permittivity value for such a layer, e.g., approximately 3.9 for a layer of silicon dioxide. Such reduction in the overall capacitance of such devices is undesirable for many reasons. Moreover, if a high-k dielectric material, e.g., tantalum pentoxide, is deposited on a conductive layer, such as polysilicon, an interfacial dielectric layer, e.g., silicon dioxide, tends to form between the high-k material and the conductive layer. In turn, the presence of the relatively low permittivity interfacial layers tends to greatly reduce the effectiveness of the high-k material.

The present invention is directed to a device and various methods that may solve, or at least reduce, some or all of the aforementioned problems.

### SUMMARY OF THE INVENTION

The present invention is generally directed to various novel dielectric stacks that may be used in integrated circuit devices, and various methods of making same. In one illustrative embodiment, a capacitor is provided which is comprised of a first conductive layer, a first dielectric layer formed above the first conductive layer, the first dielectric layer comprised of a material selected from the group consisting of hafnium silicate, zirconium silicate and aluminum silicate, a second dielectric layer formed above the first dielectric layer, the second dielectric layer comprised of a material selected from the group consisting of hafnium oxide, zirconium oxide and aluminum oxide, and a second conductive layer formed above the second dielectric layer. In some embodiments, the first conductive layer may be comprised of a silicon-containing material or a metal nitride.

In another illustrative embodiment, a memory cell is provided which is comprised of a transistor and a capacitor coupled to the transistor, the capacitor being comprised of a first conductive layer, a first dielectric layer formed above the first conductive layer, the first dielectric layer comprised of a material selected from the group consisting of hafnium silicate, zirconium silicate and aluminum silicate, a second dielectric layer formed above the first dielectric layer, the second dielectric layer comprised of a material selected from the group consisting of hafnium oxide, zirconium oxide and aluminum oxide, and a second conductive layer formed above the second dielectric layer.

In yet another illustrative embodiment, a transistor is provided which is comprised of a gate electrode formed above a semiconducting substrate and a first and a second dielectric layer positioned between the substrate and the gate electrode, the second dielectric layer being positioned between the first dielectric layer and the gate electrode, the first dielectric layer being formed above the substrate and being comprised of a material selected from the group consisting of hafnium silicate, zirconium silicate and aluminum silicate, the second dielectric layer being comprised of a material selected from the group consisting of hafnium oxide, zirconium oxide and aluminum oxide.

In still another illustrative embodiment, a method of forming a capacitor is provided which comprises forming a first conductive layer, depositing a first dielectric layer comprised of at least one of hafnium silicate, zirconium silicate and aluminum silicate above the first conductive layer, depositing a second dielectric layer comprised of at least one of hafnium oxide, zirconium oxide and aluminum oxide above the first dielectric layer and forming a second conductive layer above the second dielectric layer.

### BRIEF DESCRIPTION OF THE DRAWINGS

The invention may be understood by reference to the following description taken in conjunction with the accompanying drawings, in which like reference numerals identify like elements, and in which:

FIGS. 1A-1F depict one illustrative process flow for forming a novel dielectric stack for a capacitor structure in accordance with one illustrative embodiment; and

FIG. 2 is a cross-sectional view of another illustrative embodiment of the present invention employed in the context of a field effect transistor.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

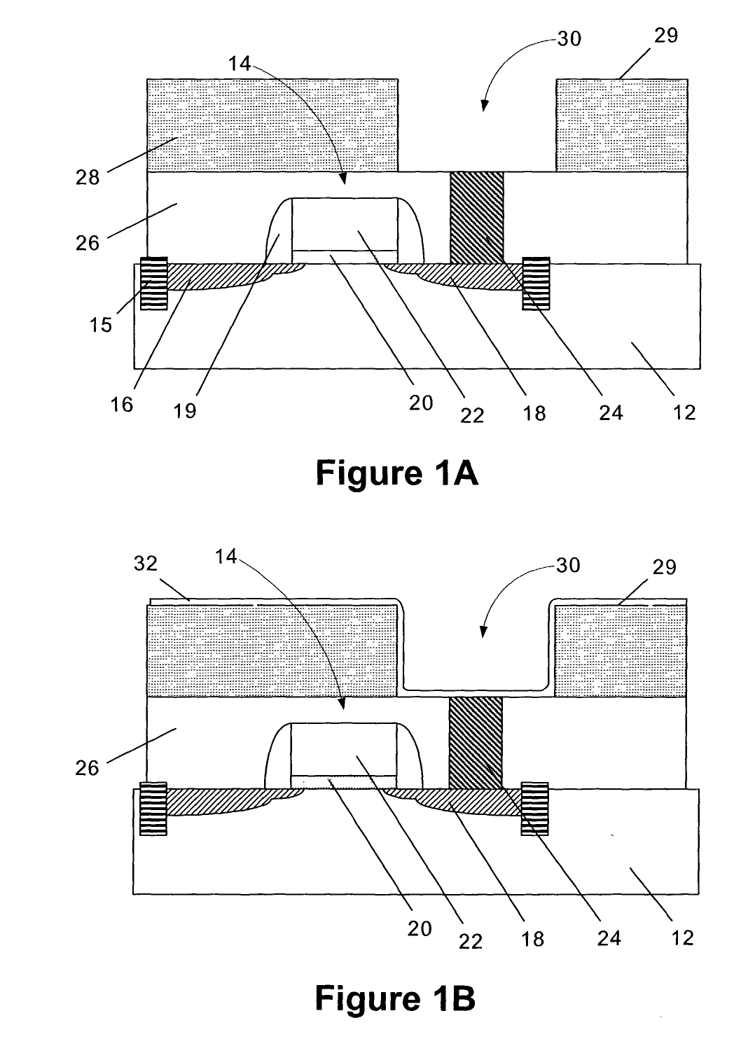

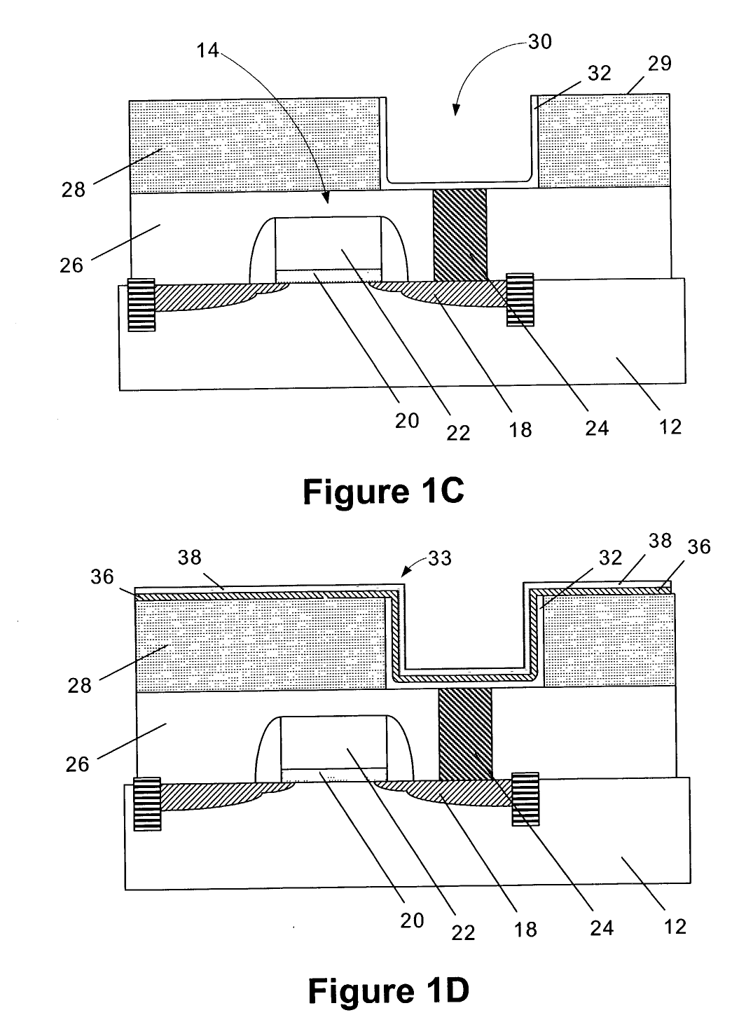

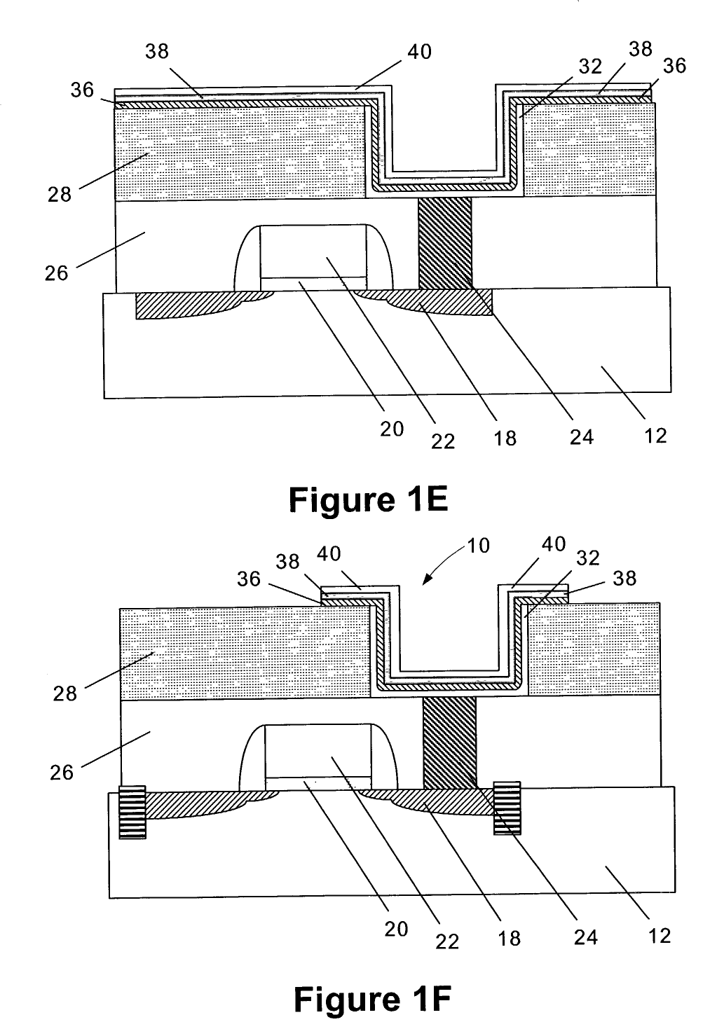

The present invention will now be described in the illustrative context of forming a capacitor structure 10 (see FIG. 1F) for an integrated circuit device. However, as will be understood by those skilled in the art after a complete reading of the present application, the present invention should not be considered as limited in use with capacitor structures only. Rather, the present invention may be employed in a variety of different applications in the art of semiconductor manufacturing. For example, the present novel dielectric stack combination may be employed as a gate insulation layer for any of a variety of field effect transistors. Thus, the present invention should not be considered as limited to any particular type of structure or integrated circuit device unless such limitations are clearly set forth in the appended claims.

As shown in FIG. 1A, a pass transistor 14 is formed above a semiconducting substrate 12. The transistor 14 is comprised of a source region 16, a drain region 18, sidewall spacers 19, a gate insulation layer 20 and a gate electrode 22. The transistor 14 is electrically isolated from other structures by isolation regions 15 formed in the substrate 12. Additional components of the transistor 14, such as various metal silicide regions formed above the gate electrode 22 and the source/drain regions 16, 18, are not depicted for purposes of clarity. Also depicted in FIG. 1A is a conductive plug 24 formed in a layer of insulating material 26. The conductive plug 24 extends through the layer of insulating material 26 to contact the drain region 18. A second layer of insulating material 28 is formed above the layer of insulating material 26. An opening 30 is formed in the second layer of insulating material 28 using known photolithography and etching techniques. Pursuant to the present invention, a capacitor having a novel dielectric stack will be formed in the opening 30, as described more fully below.

The various components and structures depicted in FIG. 1A may be comprised of a variety of known materials, and they may be formed using a variety of known processing techniques. For example, the gate insulating layer 20 may be comprised of silicon dioxide, it may have a thickness of approximately 5-8 nm, and it may be formed by a thermal oxidation process or by a deposition process, such as a chemical vapor deposition (“CVD”) process. The gate electrode 22 may be comprised of, for example, a doped polycrystalline silicon (polysilicon), and it may be formed by depositing a layer of polysilicon and patterning the layer of polysilicon using known photolithography and etching techniques. The conductive plug 24 may be comprised of a variety of materials, such as a doped polysilicon, tungsten, or other suitable materials. The layers of insulating material 26, 28 may be comprised of a variety of materials, such as boron phosphosilicate glass (BPSG), borosilicate glass (BSG), phosphosilicate glass (PSG), silicon dioxide, or other like materials. Thus, the present invention should not be considered as limited to any of the structures or materials referenced herein for the components depicted in FIG. 1A unless such limitations are clearly set forth in the appended claims.

As shown in FIG. 1B, a first conductive layer 32 is conformally deposited above the surface 29 and in the opening 30 in the second layer of insulating material 28. In general, the first conductive layer 32 will serve as the lower electrode for the capacitor structure 10 to be formed in the opening 30. The first conductive layer 32 may have a thickness that, in one illustrative embodiment, ranges from approximately 20-30 nm, and it may be formed by a variety of techniques, e.g., chemical vapor deposition (“CVD”), plasma enhanced chemical vapor deposition (“PECVD”), etc. The first conductive layer 32 may be comprised of a silicon-containing material, such as, for example, polysilicon (doped or undoped), hemispherical grained polysilicon (HSG), etc. The first conductive layer 32 may also be comprised of a metal nitride material, such as, for example, titanium nitride, tungsten nitride, tantalum nitride, hafnium nitride, etc. Although the first conductive layer 32 is depicted as being relatively smooth, in actual devices the surface of the first conductive layer 32 may be roughened to increase the surface area of the layer. Thereafter, as shown in FIG. 1C, a chemical mechanical polishing process is performed to remove the portions of the first conductive layer 32 positioned above the surface 29 of the second layer of insulating material 28.

Next, as shown in FIG. 1D, the present invention involves the formation of a stack 33 of dielectric materials. More particularly, the dielectric stack 33 is comprised of a first dielectric layer 36 deposited on the first conductive layer 32 and a second dielectric layer 38 deposited on the first dielectric layer 36. The first and second dielectric layers 36, 38 may be formed using a variety of techniques, such as atomic layer deposition (“ALD”) or chemical vapor deposition (“CVD”), plasma enhanced chemical vapor deposition (“PECVD”), a sol-gel process, electroplating, electroless plating, physical vapor deposition (“PVD”), etc.

The first dielectric layer 36 may be comprised of a metal silicate such as, for example, hafnium silicate (Hfₓ Si_{y} O_{z}), zirconium silicate (Zrₓ Si_{y} O_{z}), or aluminum silicate (Alₓ Si_{y} O_{z}). The permittivity of each of these materials is, respectively, approximately 10-20, 10-40, and 6-12. The first dielectric layer 36 is comprised of a material that does not tend to react with the silicon present in the first conductive layer 32. It should be understood that the precise values for “x,” “y” and “z” for the materials identified above may vary depending upon the various precursors used to form the layers and the exact production methodologies employed. For example, the values of “x,” “y” and “z” may range from approximately 0.01 to 0.99. The thickness of the first dielectric layer 36 may vary. In one illustrative embodiment, the thickness of the first dielectric layer 36 may vary from approximately 1-100 nm.

The second dielectric layer 38 may be comprised of a metal oxide such as, for example, hafnium oxide (HfO₂), zirconium oxide (ZrO₂) or aluminum oxide (Al₂O₃). The permittivity of each of these materials is, respectively, approximately 20-35, 25-40, and 8-12. The thickness of the second dielectric layer 38 may vary and, in one illustrative embodiment, it may vary between approximately 1-100 nm.

Moreover, as will be understood after a complete reading of the present invention, the various materials for the first dielectric layer 36 and the second dielectric layer 38 may be used in various combinations. For example, the first dielectric layer 36 may be comprised of hafnium silicate and the second dielectric layer 38 may be comprised of any of the metal oxides identified above, e.g., hafnium oxide, zirconium oxide and aluminum oxide. Similarly, the second dielectric layer 36 may be comprised of zirconium silicate and the second dielectric layer 38 may be comprised of hafnium oxide, zirconium oxide or aluminum oxide. Lastly, the first dielectric layer 36 may be comprised of aluminum silicate and the second dielectric layer 38 may be comprised of any of the above-identified metal oxides. Additionally, each of the metal oxides may be used as the second dielectric layer 38 in conjunction when any of the metal silicates identified above is used as the first dielectric layer 36. The use of hafnium silicate may offer additional advantages due to its amorphous structure, and hence greater compatibility with silicon-containing materials, as compared to the other silicates, e.g., zirconium silicate and aluminum silicate. In one particular embodiment of the present invention, a combination of hafnium silicate/hafnium oxide or hafnium silicate/zirconium oxide may be employed.

In one particular embodiment of the present invention, the first and second dielectric layers 36, 38 may be formed by an ALD process. In general, ALD includes exposing an initial substrate to a first chemical species to accomplish chemisorption of the species onto the substrate. Theoretically, the chemisorption forms a monolayer that is uniformly one atom or molecule thick on the entire exposed initial substrate. In other words, a saturated monolayer. Practically, chemisorption might not occur on all portions of the substrate. Such an imperfect monolayer is nevertheless considered a monolayer in the context of this description. In many applications, merely a substantially saturated monolayer may be suitable. A substantially saturated monolayer is one that will yield a deposited layer exhibiting the quality and/or properties desired for such layer.

More particularly, such an ALD process may involve performing an ALD process to form the first dielectric layer 36 on the first conductive layer 32, followed by an in situ atomic layer deposition of the second dielectric layer 38 on the first dielectric layer 36. Depending upon the composition of the first and second dielectric layers 36, 38, this may involve simply stopping the pulses of one or more of the precursors used in the ALD process. In some cases, for example where the first dielectric layer 36 is comprised of hafnium silicate and the second dielectric layer is comprised of, e.g., aluminum oxide, the ALD chamber may need to be purged using an inert gas after the first dielectric layer 36 is formed. Thereafter, the appropriate precursor materials may be used to form the layer of aluminum oxide.

As a further example, in one illustrative embodiment, the first dielectric layer 36 may be comprised of aluminum silicate and the second dielectric layer 38 may be comprised of aluminum oxide. In that situation, any of the following chemistries may be employed in an ALD process to form the first dielectric layer 36 comprised of aluminum silicate:

Si(OnBu)₄+Al(CH₃)₃→AlxSiyOz+byproduct

or

SiCl₄+Al (OCH(CH₃)₂)₃→AlxSiyOz+byproduct

or

SiH₄+Al (OCH(CH₃)₂)₃→AlxSiyOz+byproduct

After the layer of aluminum silicate is formed, an in situ ALD process may be performed to form the second dielectric layer 38 comprised of aluminum oxide above the aluminum silicate layer in accordance with the following chemistry:

Al(CH₃)₃+Al (OCH(CH₃)₂)₃→Al2O₃+3CH₃CH(CH₃)₂

Alternatively, any of a variety of standard ALD chemistries may be employed to form the second dielectric layer 38 comprised of aluminum oxide.

Next, as shown in FIG. 1E, a second conductive layer 40 is formed above the dielectric stack 33 comprised of the first dielectric layer 36 and the second dielectric layer 38. Ultimately, portions of the conductive layer 40 will become the upper electrode for the capacitor 10. The conductive layer 40 may be comprised of a variety of materials, such as polysilicon, titanium nitride, a metal, etc., and it may be formed by a variety of known techniques. Thereafter, as shown in FIG. 1F, excess portions of the conductive layer 40 and the first and second dielectric layers 36, 38 are removed (by etching) to define the capacitor 10. Further steps to create a functional memory cell containing the capacitor 10 may now be carried out such as the formation of various insulating layers and various wiring connects, all of which are known to those skilled in the art.

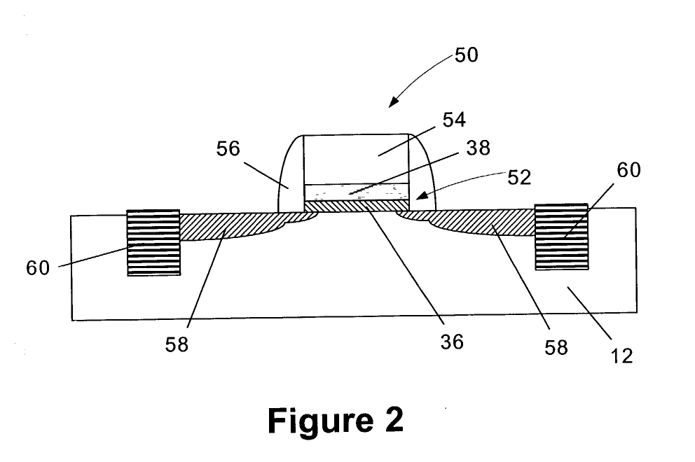

FIG. 2 is a cross-sectional view of an illustrative transistor 50 incorporating the novel dielectric stack 33 of the present invention. More particularly, the gate insulation layer 52 for the transistor 50 may be comprised of the first dielectric layer 36 formed on the substrate 12 and the second dielectric layer 38 formed on the first dielectric layer 36. As discussed above, the thickness and composition of these layers 36, 38 may vary depending upon the particular application. Thereafter, traditional processing techniques may be employed to complete the formation of the various components of the transistor.

The layers 36, 38 may be formed in the manner described above. That is, the layer 36 may, in one embodiment, be formed on the substrate 12 by an ALD process. Thereafter, an in situ ALD process may be performed to form the second dielectric layer 38 above the first dielectric layer 36. The transistor 50 further includes a gate electrode 54, sidewall spacer 56, and source/drain regions 58. The transistor 50 is electrically isolated within the substrate 12 by isolation regions 60 formed therein. It should be understood that the transistor 50 depicted in FIG. 2 is intended to be representative in nature. That is, the transistor 50 may be part of a memory device, e.g., a pass transistor, part of a logic device, such as a microprocessor, or it may be a portion of any other type of integrated circuit device. Thus, it should be clear from the foregoing that the novel dielectric stack 33 of the present invention may be employed with a variety of different types of devices, e.g., transistors, capacitors, etc., and it may be employed in a variety of different technologies, e.g., NMOS, PMOS, CMOS, etc.

Through use of the present invention, a novel dielectric stack is provided in an effort to reduce or limit reaction between silicon atoms (in a substrate or other layer) and the second dielectric layer 38 comprised of a high-k material. It is believed that, since the (interfacial) first dielectric layer 36 is comprised of both silicon oxide and a metal oxide, there will be no abrupt transition between dissimilar metals, as would be the case if a metal oxide, e.g., aluminum oxide, were to be formed directly on the silicon-containing surface. In the case where a metal oxide, such as aluminum oxide, is formed directly on a silicon-containing surface, the materials tend to diffuse through each other due to the large concentration difference between the two materials. However, in the case where the dielectric stack of the present invention is employed, e.g., silicon-aluminum silicate - aluminum oxide, there will be very little, if any, diffusion.

As a result of the present invention, it is believed that degradation in the effectiveness of the high-k dielectric material, i.e., the second dielectric layer 38, may be reduced or avoided through use of the present invention. By reducing or preventing a reaction between the silicon surfaces and the high-k second dielectric layer 38, the overall capacitance of the stack 33 may be maintained at a higher value than that found in prior art devices. For example, through use of the present invention, the overall permittivity of the combined metal silicate/metal oxide stack may be approximately 60-100% of the permittivity of the high-k metal oxide layer alone. Thus, in accordance with the present invention, a novel dielectric stack may be employed to improve the storage capabilities of capacitor structures and/or to provide a gate insulation layer for various transistors. As a result, devices may be made smaller, device performance may be enhanced and overall product and manufacturing efficiencies may be realized.

The present invention is generally directed to various novel dielectric stacks that may be used in integrated circuit devices, and various methods of making same. In one illustrative embodiment, a capacitor is provided which is comprised of a first conductive layer, a first dielectric layer formed above the first conductive layer, the first dielectric layer comprised of a material selected from the group consisting of hafnium silicate, zirconium silicate and aluminum silicate, a second dielectric layer formed above the first dielectric layer, the second dielectric layer comprised of a material selected from the group consisting of hafnium oxide, zirconium oxide and aluminum oxide, and a second conductive layer formed above the second dielectric layer.

In another illustrative embodiment, a memory cell is provided which is comprised of a transistor and a capacitor coupled to the transistor, the capacitor being comprised of a first conductive layer, a first dielectric layer formed above the first conductive layer, the first dielectric layer comprised of a material selected from the group consisting of hafnium silicate, zirconium silicate and aluminum silicate, a second dielectric layer formed above the first dielectric layer, the second dielectric layer comprised of a material selected from the group consisting of hafnium oxide, zirconium oxide and aluminum oxide, and a second conductive layer formed above the second dielectric layer.

In yet another illustrative embodiment, a transistor is provided which is comprised of a gate electrode formed above a semiconducting substrate and a first and a second dielectric layer positioned between the substrate and the gate electrode, the second dielectric layer being positioned between the first dielectric layer and the gate electrode, the first dielectric layer being formed above the substrate and being comprised of a material selected from the group consisting of hafnium silicate, zirconium silicate and aluminum silicate, the second dielectric layer being comprised of a material selected from the group consisting of hafnium oxide, zirconium oxide and aluminum oxide.

In still another illustrative embodiment, a method of forming a capacitor is provided which comprises forming a first conductive layer, depositing a first dielectric layer comprised of at least one of hafnium silicate, zirconium silicate and aluminum silicate above the first conductive layer, depositing a second dielectric layer comprised of at least one of hafnium oxide, zirconium oxide and aluminum oxide above the first dielectric layer and forming a second conductive layer above the second dielectric layer.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A capacitor, comprising:
a first conductive layer;
a first dielectric layer formed above said first conductive layer, said first dielectric layer comprised of a material selected from the group consisting of hafnium silicate, zirconium silicate and aluminum silicate;
a second dielectric layer formed above said first dielectric layer, said second dielectric layer comprised of a material selected from the group consisting of hafnium oxide, zirconium oxide and aluminum oxide; and
a second conductive layer formed above said second dielectric layer.

2. The capacitor of claim 1, wherein the first conductive layer is comprised of a silicon-containing material.

3. The capacitor of claim 1, wherein the first conductive layer is comprised of a metal nitride.

4. The capacitor of claim 1, wherein said first conductive layer is comprised of at least one of a doped polysilicon, an undoped polysilicon and a hemispherical grained polysilicon.

5. The capacitor of claim 1, wherein said first conductive layer is comprised of at least one of titanium nitride, tantalum nitride, tungsten nitride and hafnium nitride.

6. The capacitor of claim 1, wherein said first dielectric layer has a thickness ranging from approximately 1-100 nm.

7. The capacitor of claim 1, wherein said second dielectric layer has a thickness ranging from approximately 1-100 nm.

8. The capacitor of claim 1, wherein said second conductive layer is comprised of at least one of polysilicon, titanium nitride and a metal.

9. The capacitor of claim 1, wherein said first conductive layer is a first electrode for said capacitor.

10. The capacitor of claim 1, wherein said second conductive layer is a second electrode for said capacitor.

11. A capacitor, comprising:
a first conductive layer comprised of a silicon-containing material;
a first dielectric layer formed above said first conductive layer, said first dielectric layer comprised of a material selected from the group consisting of hafnium silicate, zirconium silicate and aluminum silicate;
a second dielectric layer formed above said first dielectric layer, said second dielectric layer comprised of a material selected from the group consisting of hafnium oxide, zirconium oxide and aluminum oxide; and
a second conductive layer formed above said second dielectric layer.

12. The capacitor of claim 11, wherein said first conductive layer is comprised of at least one of a doped polysilicon, an undoped polysilicon and a hemispherical grained polysilicon.

13. The capacitor of claim 11, wherein said first dielectric layer has a thickness ranging from approximately 1-100 nm.

14. The capacitor of claim 11, wherein said second dielectric layer has a thickness ranging from approximately 1-100 nm.

15. The capacitor of claim 11, wherein said second conductive layer is comprised of at least one of polysilicon, titanium nitride and a metal.

16. The capacitor of claim 11, wherein said first conductive layer is a first electrode for said capacitor.

17. The capacitor of claim 11, wherein said second conductive layer is a second electrode for said capacitor.

18. An integrated circuit, comprising:
a capacitor, comprising:
a first conductive layer;
a first dielectric layer formed above said first conductive layer, said first dielectric layer comprised of a material selected from the group consisting of hafnium silicate, zirconium silicate and aluminum silicate;
a second dielectric layer formed above said first dielectric layer, said second dielectric layer comprised of a material selected from the group consisting of hafnium oxide, zirconium oxide and aluminum oxide; and
a second conductive layer formed above said second dielectric layer.

19. The integrated circuit of claim 18, wherein the first conductive layer is comprised of a silicon-containing material.

20. The integrated circuit of claim 18, wherein the first conductive layer is comprised of a metal nitride.

21. The integrated circuit of claim 18, wherein said first conductive layer is comprised of at least one of a doped polysilicon, an undoped polysilicon and a hemispherical grained polysilicon.

22. The integrated circuit of claim 18, wherein said first conductive layer is comprised of at least one of titanium nitride, tantalum nitride, tungsten nitride and hafnium nitride.

23. The integrated circuit of claim 18, wherein said first dielectric layer has a thickness ranging from approximately 1-100 nm.

24. The integrated circuit of claim 18, wherein said second dielectric layer has a thickness ranging from approximately 1-100 nm.

25. The integrated circuit of claim 18, wherein said second conductive layer is comprised of at least one of polysilicon, titanium nitride and a metal.

26. The integrated circuit of claim 18, wherein said first conductive layer is a first electrode for said capacitor.

27. The integrated circuit of claim 18, wherein said second conductive layer is a second electrode for said capacitor.

28. A memory cell, comprising:
a transistor; and
a capacitor coupled to the transistor, the capacitor comprising:
a first conductive layer;
a first dielectric layer formed above said first conductive layer, said first dielectric layer comprised of a material selected from the group consisting of hafnium silicate, zirconium silicate and aluminum silicate;
a second dielectric layer formed above said first dielectric layer, said second dielectric layer comprised of a material selected from the group consisting of hafnium oxide, zirconium oxide and aluminum oxide; and
a second conductive layer formed above said second dielectric layer.

29. The memory cell of claim 28, wherein the first conductive layer is comprised of a silicon-containing material.

30. The memory cell of claim 28, wherein the first conductive layer is comprised of a metal nitride.

31. The memory cell of claim 28, wherein said first conductive layer is comprised of at least one of a doped polysilicon, an undoped polysilicon and a hemispherical grained polysilicon.

32. The memory cell of claim 28, wherein said first conductive layer is comprised of at least one of titanium nitride, tantalum nitride, tungsten nitride and hafnium nitride.

33. The memory cell of claim 28, wherein said first dielectric layer has a thickness ranging from approximately 1-100 nm.

34. The memory cell of claim 28, wherein said second dielectric layer has a thickness ranging from approximately 1-100 nm.

35. The memory cell of claim 28, wherein said second conductive layer is comprised of at least one of polysilicon, titanium nitride and a metal.

36. The memory cell of claim 28, wherein said first conductive layer is a first electrode for said capacitor.

37. The memory cell of claim 28, wherein said second conductive layer is a second electrode for said capacitor.

38. A capacitor, comprising:
a first conductive layer;
a first dielectric layer formed above said first conductive layer, said first dielectric layer being comprised of hafnium silicate;
a second dielectric layer formed above said first dielectric layer, said second dielectric layer being comprised of hafnium oxide; and
a second conductive layer formed above said second dielectric layer.

39. A capacitor, comprising:
a first conductive layer;
a first dielectric layer formed above said first conductive layer, said first dielectric layer being comprised of hafnium silicate;
a second dielectric layer formed above said first dielectric layer, said second dielectric layer being comprised of zirconium oxide; and
a second conductive layer formed above said second dielectric layer.

40. A capacitor, comprising:
a first conductive layer;
a first dielectric layer formed above said first conductive layer, said first dielectric layer being comprised of hafnium silicate;
a second dielectric layer formed above said first dielectric layer, said second dielectric layer being comprised of aluminum oxide; and
a second conductive layer formed above said second dielectric layer.

41. A capacitor, comprising:
a first conductive layer;
a first dielectric layer formed above said first conductive layer, said first dielectric layer being comprised of zirconium silicate;
a second dielectric layer formed above said first dielectric layer, said second dielectric layer being comprised of hafnium oxide; and
a second conductive layer formed above said second dielectric layer.

42. A capacitor, comprising:
a first conductive layer;
a first dielectric layer formed above said first conductive layer, said first dielectric layer being comprised of zirconium silicate;
a second dielectric layer formed above said first dielectric layer, said second dielectric layer being comprised of zirconium oxide; and
a second conductive layer formed above said second dielectric layer.

43. A capacitor, comprising:
a first conductive layer;
a first dielectric layer formed above said first conductive layer, said first dielectric layer being comprised of zirconium silicate;
a second dielectric layer formed above said first dielectric layer, said second dielectric layer being comprised of aluminum oxide; and
a second conductive layer formed above said second dielectric layer.

44. A capacitor, comprising:
a first conductive layer;
a first dielectric layer formed above said first conductive layer, said first dielectric layer being comprised of aluminum silicate;
a second dielectric layer formed above said first dielectric layer, said second dielectric layer being comprised hafnium oxide; and
a second conductive layer formed above said second dielectric layer.

45. A capacitor, comprising:
a first conductive layer;
a first dielectric layer formed above said first conductive layer, said first dielectric layer being comprised of aluminum silicate;
a second dielectric layer formed above said first dielectric layer, said second dielectric layer being comprised of zirconium oxide; and
a second conductive layer formed above said second dielectric layer.

46. A capacitor, comprising:
a first conductive layer;
a first dielectric layer formed above said first conductive layer, said first dielectric layer being comprised of aluminum silicate;
a second dielectric layer formed above said first dielectric layer, said second dielectric layer being comprised of aluminum oxide; and
a second conductive layer formed above said second dielectric layer.

47. A transistor, comprising:
a gate electrode formed above a semiconducting substrate; and
a first and a second dielectric layer positioned between said substrate and said gate electrode, said second dielectric layer being positioned between said first dielectric layer and said gate electrode, said first dielectric layer being formed above said substrate and being comprised of a material selected from the group consisting of hafnium silicate, zirconium silicate and aluminum silicate, said second dielectric layer being comprised of a material selected from the group consisting of hafnium oxide, zirconium oxide and aluminum oxide.

48. The transistor of claim 47, wherein said first conductive layer is comprised of at least one of a doped polysilicon, an undoped polysilicon and a hemispherical grained polysilicon.

49. The transistor of claim 47, wherein said gate electrode is comprised of polysilicon.

50. A transistor, comprising:
a gate electrode formed above a semiconducting substrate comprised of silicon; and
a first and a second dielectric layer positioned between said substrate and said gate electrode, said second dielectric layer being positioned between said first dielectric layer and said gate electrode, said first dielectric layer being formed above said substrate and being comprised of hafnium silicate, said second dielectric layer being comprised of hafnium oxide.

51. A transistor, comprising:
a gate electrode formed above a semiconducting substrate comprised of silicon; and
a first and a second dielectric layer positioned between said substrate and said gate electrode, said second dielectric layer being positioned between said first dielectric layer and said gate electrode, said first dielectric layer being formed above said substrate and being comprised of hafnium silicate, said second dielectric layer being comprised of zirconium oxide.

52. A transistor, comprising:
a gate electrode formed above a semiconducting substrate comprised of silicon; and
a first and a second dielectric layer positioned between said substrate and said gate electrode, said second dielectric layer being positioned between said first dielectric layer and said gate electrode, said first dielectric layer being formed above said substrate and being comprised of hafnium silicate, said second dielectric layer being comprised of aluminum oxide.

53. A transistor, comprising:
a gate electrode formed above a semiconducting substrate comprised of silicon; and
a first and a second dielectric layer positioned between said substrate and said gate electrode, said second dielectric layer being positioned between said first dielectric layer and said gate electrode, said first dielectric layer being formed above said substrate and being comprised of zirconium silicate, said second dielectric layer being comprised of hafnium oxide.

54. A transistor, comprising:
a gate electrode formed above a semiconducting substrate comprised of silicon; and
a first and a second dielectric layer positioned between said substrate and said gate electrode, said second dielectric layer being positioned between said first dielectric layer and said gate electrode, said first dielectric layer being formed above said substrate and being comprised of zirconium silicate, said second dielectric layer being comprised of zirconium oxide.

55. A transistor, comprising:
a gate electrode formed above a semiconducting substrate comprised of silicon; and
a first and a second dielectric layer positioned between said substrate and said gate electrode, said second dielectric layer being positioned between said first dielectric layer and said gate electrode, said first dielectric layer being formed above said substrate and being comprised of zirconium silicate, said second dielectric layer being comprised of aluminum oxide.

56. A transistor, comprising:
a gate electrode formed above a semiconducting substrate comprised of silicon; and
a first and a second dielectric layer positioned between said substrate and said gate electrode, said second dielectric layer being positioned between said first dielectric layer and said gate electrode, said first dielectric layer being formed above said substrate and being comprised of aluminum silicate, said second dielectric layer being comprised of hafnium oxide.

57. A transistor, comprising:
a gate electrode formed above a semiconducting substrate comprised of silicon; and
a first and a second dielectric layer positioned between said substrate and said gate electrode, said second dielectric layer being positioned between said first dielectric layer and said gate electrode, said first dielectric layer being formed above said substrate and being comprised of aluminum silicate, said second dielectric layer being comprised of zirconium oxide.

58. A transistor, comprising:
a gate electrode formed above a semiconducting substrate comprised of silicon; and
a first and a second dielectric layer positioned between said substrate and said gate electrode, said second dielectric layer being positioned between said first dielectric layer and said gate electrode, said first dielectric layer being formed above said substrate and being comprised of aluminum silicate, said second dielectric layer being comprised of aluminum oxide.

59. A method of forming a capacitor, comprising:
forming a first conductive layer;
depositing a first dielectric layer comprised of at least one of hafnium silicate, zirconium silicate and aluminum silicate above said first conductive layer;
depositing a second dielectric layer comprised of at least one of hafnium oxide, zirconium oxide and aluminum oxide above said first dielectric layer; and forming a second conductive layer above said-second dielectric layer.

60. The method of claim 59, wherein forming a first conductive layer comprises forming a first conductive layer comprised of a silicon-containing material.

61. The method of claim 59, wherein forming a first conductive layer comprises forming a first conductive layer comprised of a metal nitride.

62. The method of claim 59, wherein forming a first conductive layer comprises forming a first conductive layer comprised of at least one of a doped polysilicon, an undoped polysilicon and a hemispherical grained polysilicon.

63. The method of claim 59, wherein forming a first conductive layer comprises forming a first conductive layer comprised of at least one of titanium nitride, tantalum nitride, tungsten nitride and hafnium nitride.

64. The method of claim 59, wherein forming a first conductive layer comprises depositing a first conductive layer.

65. The method of claim 59, wherein said first and second dielectric layers are deposited by an atomic layer deposition process.

66. The method of claim 59, wherein forming a second conductive layer above said second dielectric layer comprises forming a second conductive layer comprised of at least one of polysilicon, titanium nitride and a metal.

67. A method of forming a capacitor, comprising:
depositing a first conductive layer comprised of a silicon-containing material;
depositing a first dielectric layer comprised of hafnium silicate above said first conductive layer;
depositing a second dielectric layer comprised of hafnium oxide above said first dielectric layer; and
forming a second conductive layer above said second dielectric layer.

68. The method of claim 67, wherein said first and second dielectric layers are deposited by an atomic layer deposition process.

69. A method of forming a capacitor, comprising:
depositing a first conductive layer comprised of a silicon-containing material;
depositing a first dielectric layer comprised of hafnium silicate above said first conductive layer;
depositing a second dielectric layer comprised of zirconium oxide above said first dielectric layer; and
forming a second conductive layer above said second dielectric layer.

70. The method of claim 69, wherein said first and second dielectric layers are deposited by an atomic layer deposition process.

71. A method of forming a capacitor, comprising:
depositing a first conductive layer comprised of a silicon-containing material;
depositing a first dielectric layer comprised of hafnium silicate above said first conductive layer;
depositing a second dielectric layer comprised of aluminum oxide above said first dielectric layer; and
forming a second conductive layer above said second dielectric layer.

72. The method of claim 71, wherein said first and second dielectric layers are deposited by an atomic layer deposition process.

73. A method of forming a capacitor, comprising:
depositing a first conductive layer comprised of a silicon-containing material;
depositing a first dielectric layer comprised of zirconium silicate above said first conductive layer;
depositing a second dielectric layer comprised of hafnium oxide above said first dielectric layer; and
forming a second conductive layer above said second dielectric layer.

74. The method of claim 73, wherein said first and second dielectric layers are deposited by an atomic layer deposition process.

75. A method of forming a capacitor, comprising:
depositing a first conductive layer comprised of a silicon-containing material;
depositing a first dielectric layer comprised of zirconium silicate above said first conductive layer;
depositing a second dielectric layer comprised of zirconium oxide above said first dielectric layer; and
forming a second conductive layer above said second dielectric layer.

76. The method of claim 75, wherein said first and second dielectric layers are deposited by an atomic layer deposition process.

77. A method of forming a capacitor, comprising:
depositing a first conductive layer comprised of a silicon-containing material;
depositing a first dielectric layer comprised of zirconium silicate above said first conductive layer;
depositing a second dielectric layer comprised of aluminum oxide above said first dielectric layer; and
forming a second conductive layer above said second dielectric layer.

78. The method of claim 77, wherein said first and second dielectric layers are deposited by an atomic layer deposition process.

79. A method of forming a capacitor, comprising:
depositing a first conductive layer comprised of a silicon-containing material;
depositing a first dielectric layer comprised of aluminum silicate above said first conductive layer;
depositing a second dielectric layer comprised of hafnium oxide above said first dielectric layer; and
forming a second conductive layer above said second dielectric layer.

80. The method of claim 79, wherein said first and second dielectric layers are deposited by an atomic layer deposition process.

81. A method of forming a capacitor, comprising:
depositing a first conductive layer comprised of a silicon-containing material;
depositing a first dielectric layer comprised of aluminum silicate above said first conductive layer;
depositing a second dielectric layer comprised of zirconium oxide above said first dielectric layer; and
forming a second conductive layer above said second dielectric layer.

82. The method of claim 81, wherein said first and second dielectric layers are deposited by an atomic layer deposition process.

83. A method of forming a capacitor, comprising:
depositing a first conductive layer comprised of a silicon-containing material;
depositing a first dielectric layer comprised of aluminum silicate above said first conductive layer;
depositing a second dielectric layer comprised of aluminum oxide above said first dielectric layer; and
forming a second conductive layer above said second dielectric layer.

84. The method of claim 83, wherein said first and second dielectric layers are deposited by an atomic layer deposition process.
